(19) United States
(12) Patent Application Publication
(10) Pub. No.: US 2004/0036172 A1
(43) Pub. Date: Feb. 26, 2004

(54) Semiconductor device package with integrated heatspreader

(76) Inventors: Chikara Azuma, Beppu-city (JP); Morio Nakao, Hiji-machi (JP)

Correspondence Address: TEXAS INSTRUMENTS INCORPORATED, P O BOX 655474, M/S 3999, DALLAS, TX, 75265

(21) Appl. No.: 10/227,936

(22) Filed: Aug. 26, 2002

(51) Int. Cl. H01L 23/48

(52) U.S. Cl. 257/738

(57) ABSTRACT

A packaged integrated circuit including a substrate 410 having opposing top and bottom surfaces and a chip 400 having opposing active and bottom surfaces. The chip is mounted on the top surface of the substrate such that the bottom surface of the chip is adjacent to the substrate, and such that the active surface of the chip is away from the substrate. The packaged integrated circuit also includes a thermally-conductive interposer 460 mounted on the active surface of the chip and a heatspreader 470 over the interposer. The interposer can be in contact with or attached to the heatspreader.

### BACKGROUND OF THE INVENTION

This invention is in the field of integrated circuit packages and packaging methods.

The demand for a reduction in size and an increase in complexity and performance of electronic components has driven the industry to produce smaller and more complex integrated circuits (ICs). These same trends have forced the development of IC packages having small footprints, high lead counts, and better electrical and thermal performance. At the same time, these IC packages are required to meet accepted industry standards. Thermal dissipation is a particular challenge since higher performance ICs produce more thermal energy, and the smaller packages of today allow the designer few options through which to dissipate this energy.

Some package types offer more options for the designer than do others. For example, in flip-chip package styles where the IC chip is mounted face-down on the substrate, a lid or heatspreader can easily be directly attached to the backside of the chip. Such a configuration is shown in FIG. 1, where chip 100 is mounted on substrate 110 with solder bumps 112. Lid or heatspreader 114 is also mounted on substrate 110 and is attached to the chip backside with thermal grease 116.

In wire-bonded package styles it is generally more difficult to incorporate a heatspreader because of the vertical clearance required by the wires. Some wirebonded packages, however, such as the cavity-down type, are more amenable to the use of heatspreaders. For example, in FIG. 2, the cavity down package consists of chip 200 mounted on substrate 210, which is in turn mounted on a second substrate 220. The face-down orientation of chip 200 allows a heatspreader 240 to be mounted on the opposite side of substrate 210 from the chip. A disadvantage of this approach is that the thermal path from the chip to the heatspreader 240 includes substrate 210, which is typically a material with poor thermal conductivity.

The more common wire-bonded package type is the face-up package in which the chip is mounted on a substrate which is in turn attached to a next higher level of interconnection such as a printed circuit board. Because the backside of the chip is adjacent to the printed circuit board, there is no room for attaching a heatspreader to the backside of the chip. The wires attached to the topside of the chip have a vertical extent that prevents close placement of a typical heatspreader. The package shown in FIG. 3 is one approach that has been taken to incorporate a heatspreader in a face-up wire-bonded package. Chip 300 is mounted on substrate 310. Wires 320 are bonded to the topside of the chip and to traces 330 on substrate 310. Heatspreader 340 is held in place above the chip and substrate by plastic resin encapsulant 350.

In the package of FIG. 3, a tradeoff between thermal performance and reliability must be made. The heatspreader 340 must be positioned far enough above the bond wires 320 to ensure that those two package components do not contact one another, while optimum thermal performance requires that the heatspreader be placed as close to the chip 300 as possible. Since device yield is typically of paramount importance, the thermal performance of the package is often sacrificed by designing the package with plenty of clearance between the bond wires and the heatspreader to prevent shorting of the wires to the electrically conductive heatspreader. Another drawback of this prior art package style is that it is difficult to reliably place the heatspreader relative to the chip, substrate, and other components during the molding process used to form encapsulant 350. The standard approach is known as the “drop-in” process because the heatspreader is simply dropped into the mold cavity prior to placing the substrate into the cavity. Accurate positional control of the heatspreader is difficult in such a drop-in process as the mold compound often moves the heatspreader as it flows into the mold cavity. Another problem is that this package often suffers from functional and cosmetic defects as a result of mold flash on the top of the heatspreader. This is a result of the difficulty involved in applying enough mechanical pressure to the heatspreader to push it flush with the mold die during the molding process. The fact that the heatspreader is essentially suspended above the chip and substrate means that there is no practical way through which to apply the force from the underside of the heatspreader necessary to eliminate flash over the top surface of the heatspreader. It is therefore apparent that a need exists in the industry for a reliable package capable of high thermal performance.

### BRIEF SUMMARY OF THE INVENTION

In one embodiment of the invention, a packaged integrated circuit is disclosed. It includes a substrate having opposing top and bottom surfaces and a chip having opposing active and bottom surfaces. The chip is mounted on the top surface of the substrate such that the bottom surface of the chip is adjacent to the substrate, and such that the active surface of the chip is away from the substrate. The packaged IC also includes a thermally-conductive interposer mounted on the active surface of the chip and a heatspreader over the interposer. The interposer can be in contact with or attached to the heatspreader.

In another embodiment of the invention, another packaged integrated circuit is disclosed. This packaged IC includes a substrate having opposing top and bottom surfaces and a chip having opposing active and bottom surfaces. The chip is mounted on the top surface of the substrate such that the bottom surface of the chip is adjacent the substrate and the active surface of the chip is away from the substrate. The package includes a heatspreader attached to the active surface of the chip. The heatspreader can have opposing top and bottom surfaces, with the bottom surface including a protrusion used to attach the heatspreader to the chip.

In still another embodiment of the invention, another packaged integrated circuit is disclosed. This packaged IC includes a substrate having opposing top and bottom surfaces and a chip having opposing active and bottom surfaces. The chip is mounted on the top surface of the substrate such that the bottom surface of the chip is adjacent to the substrate, and the active surface of the chip is away from the substrate. The package includes a heatspreader mounted on the substrate such that the heatspreader covers the chip. The heatspreader can be attached to the active surface of the chip as well as to the substrate. The package can also include a thermally-conductive interposer mounted on the active surface of the chip such that the heatspreader covers both the interposer and the chip. The interposer can be in contact with or attached to the heatspreader. In all of the embodiments, electrical contact between the active surface of the chip and the substrate can be made through bond wires. In addition, in all of the embodiments, encapsulant can cover the top surface of the substrate, the chip, and at least a portion of the heatspreader.

An advantage of the invention is that it improves heat dissipation in a packaged integrated circuit and the arrangement of interposers and heatspreaders described herein can be assembled with existing equipment during conventional chip packaging operations.

### BRIEF DESCRIPTION OF THE SEVERAL VIEWS OF THE DRAWINGS

The drawings are intended to aid in understanding of embodiments of the invention. It should be appreciated that the drawings are not to scale; in particular, the vertical dimension may be exaggerated to better show the details of the embodiments.

FIG. 1 is a cross-sectional diagram of a prior art flip-chip package.

FIG. 2 is a cross-sectional diagram of a prior art cavity-down package.

FIG. 3 is a cross-sectional diagram of a prior art face-up wire-bonded package.

FIG. 4 is a cross-sectional diagram of an embodiment package including a thermally conductive interposer between the chip and the heatspreader.

FIG. 5 is a cross-sectional diagram of an embodiment package including a thermally conductive interposer between the chip and the heatspreader in which the interposer is attached to the heatspreader.

FIG. 6 is a cross-sectional diagram of an embodiment package in which the heatspreader is directly attached to the active surface of the chip.

FIG. 7 is a cross-sectional diagram of an embodiment package in which a heatspreader is mounted on both the substrate and the active surface of the chip.

FIG. 8 is a cross-sectional diagram of an embodiment package in which a heatspreader is mounted on the substrate and covers the chip and a thermally conductive interposer mounted on the active surface of the chip.

FIG. 9 is a cross-sectional diagram of an embodiment package in which a heatspreader is mounted on the substrate and covers the chip and a thermally conductive interposer mounted on the active surface of the chip, and in which the interposer is attached to the heatspreader.

FIG. 10 is a plan view of the heatspreader shown in cross-section in FIGS. 7 and 8.

FIG. 11 is a plan view of an alternative heatspreader.

FIG. 12a is a plan view of an embodiment package.

FIG. 12b is a front cross-sectional view of the embodiment package shown in plan view in FIG. 12a.

FIG. 12c is a side cross-sectional view of the embodiment package shown in plan view in FIG. 12a.

FIG. 12d is a detailed view of the cross-sectional view shown in FIG. 12b.

FIG. 12e is a plan view of the bottom of the embodiment package shown in FIG. 12a.

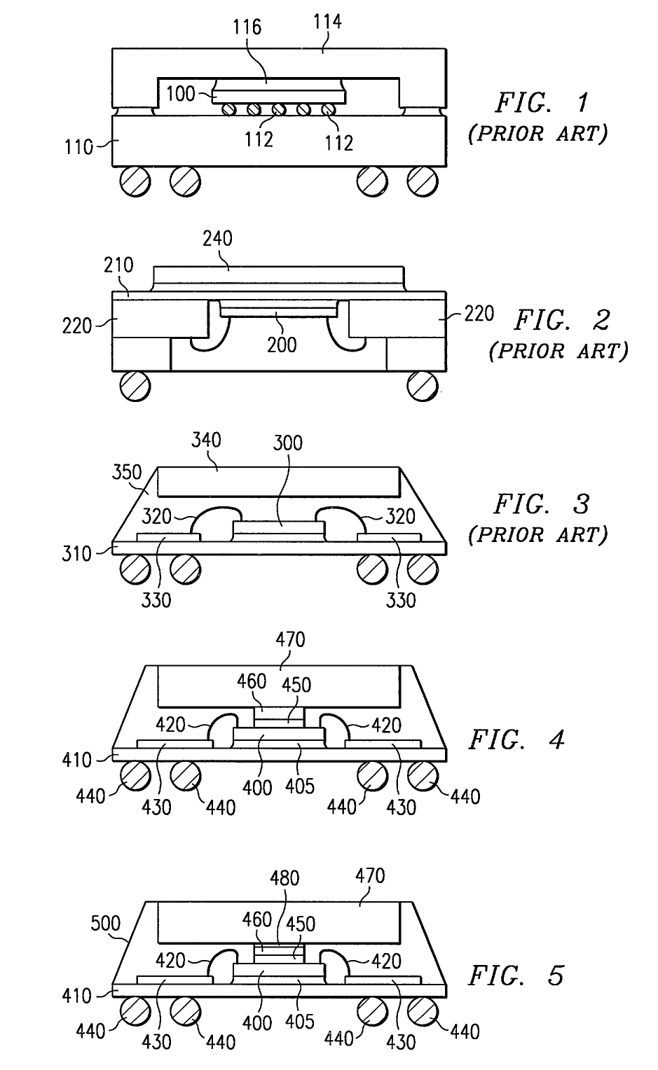

### DETAILED DESCRIPTION OF THE INVENTION

In the prior art package shown in FIG. 3, the thermal interface between the chip 300 and the heatspreader 340 is a relatively large expanse of mold compound between the chip and the heatspreader. Mold compound is a poor thermal conductor, so the thermal performance of the package is correspondingly poor. In contrast, in one embodiment of the invention, the thermal interface between the chip and the heatspreader comprises a thermal adhesive and an interposer made of a high thermally conductive material. Heat is channeled through this interface where it can be dissipated by the heatspreader and through an optional heatsink (not shown herein) externally attached to the heatspreader. FIG. 4 is a cross-sectional diagram of the embodiment package. Chip 400 is mounted on substrate 410 with adhesive 405. Bond wires 420 connect circuitry on chip 400 to traces 430 on substrate 410. Traces 430 are connected through vias (not shown) to solder balls 440, which may ultimately be used to connect the package to a printed circuit board or other higher level of interconnection. Interposer 460 is mounted on chip 400 using thermally conductive adhesive 450. An advantage of this package configuration is that the interposer can be mounted on the chip using the same equipment used to mount the chip on substrate 410. Interposer 460 is preferably a high thermal conductivity material such as copper, aluminum, or a similar material. In packages in which thermally-induced mechanical stress may be a problem, the interposer can be made of a material with particular thermal characteristics. For example, in a package containing a silicon chip, the chip is typically the dominant package component in determining how the package behaves during thermal cycling. For example, if the coefficients of thermal expansion (CTE) of the substrate, chip, and mold compound encapsulant differ substantially, the package will tend to flex and warp during thermal cycling, and will in some cases delaminate and fail. One way to address this problem is to select package materials with comparable CTEs so that the amount of warp and flex during thermal cycling is lessened. Accordingly, in this embodiment where chip 400 is silicon, interposer material could be silicon, Alloy 42, Kovar, or another material with a coefficient of thermal expansion similar to that of silicon. There may also be situations where the interposer is chosen with a CTE that counterbalances the CTE of another package component. The same is true of the materials selected for heatspreader 470. Thermal adhesive 450 is preferably a non-electrically-conductive epoxy or acrylic, filled with SiO₂, or AI₂O₃, or a similar metal oxide. The thermal adhesive is preferably in thin film tape form, but could alternatively be dispensed in liquid form, for example. It should be appreciated that other thermally-conductive adhesives, such as electrically conductive, silver-filled epoxy could be used since the surface of chip 400 is coated with silicon nitride, silicon oxy-nitride or similar passivation that electrically isolates it from the adhesive.

The stack height of the adhesive 450 and the interposer 460 is designed to only slightly exceed the highest point in the arc of bond wires 420. In this embodiment, the stack height of the chip 400 plus the adhesive 405 is about 300 μm. The arc of bond wires 420 is on the order of 250 μm above the stack height of the chip 400 and adhesive 405. Adhesive 450 has a thickness in the range of 50 to 100 μm and the total stack height of the adhesive 450 and interposer 460 is approximately 500 μm. The preferred configuration is to have the stack height of the adhesive 450 and interposer 460 exceed the arc of bond wires 420 by about 250 μm. It should be appreciated that the bond wire clearance is a tradeoff between thermal performance and reliability. The closer the wires are to the heatspreader 470, the better the thermal performance, but the wires are more likely to contact the heatspreader and create an electrical short circuit. Heatspreader 470 typically has a thickness in the range of 0.3 to 1.0 mm. In this embodiment, the heatspreader 470 is held in place by interposer 460, which is pressed onto the heatspreader to prevent movement during the flow of mold compound into the cavity. The pressure exerted on the heatspreader by the interposer also has the advantage of limiting the unwanted flow of mold compound between the interposer and heatspreader and between the top of the heatspreader and the mold die. The embodiment therefore provides a way of ensuring the accuracy of the placement of the heatspreader relative to the chip, in addition to limiting mold compound flash between the interposer and heatspreader and on top of the heatspreader. In the event that manufacturing tolerances are such that holding the heatspreader in place as described above threatens to damage chip 400, the package can be assembled using a conventional drop-in process in which the heatspreader is not held in place during the molding operation. The embodiment approach still offers advantages over prior art drop-in approaches, however, since the interposer 460 serves to improve the thermal path between the chip 400 and the heatspreader 470.

In another embodiment of the invention shown in FIG. 5, the heatspreader 470 is attached to the interposer 460 with thermally conductive adhesive 480 such as silver-or metal-oxide-filled epoxy. This approach allows even more control of the relative positions of the heatspreader and the chip during the mold process. In an alternative embodiment shown in FIG. 6, the interposer 460 of FIG. 4 is replaced by a protrusion 490 that is an integral part of the heatspreader 470. This approach offers a simpler interface between the chip 400 and the heatspreader, since only adhesive 450 is in the thermal dissipation path. Note that although the embodiments shown in FIGS. 5 and 6 are shown with the surface of the heatspreader 470 exposed at the top of the encapsulant 500, it should be appreciated that since the relative positions of the heatspreader 470 and the chip 400 are fixed by virtue of either direct or indirect attachment by adhesive, the heatspreader can be covered by mold compound. That is, it is possible to use a standard molding process, rather than a drop-in process, when the heatspreader is attached to the chip.

FIG. 7 shows an embodiment of the invention in which heatspreader 770 is directly attached to chip 700. In this case the heatspreader is shaped such that it can be mounted not only to chip 700, but also the substrate 710 over traces 730. The heatspreader is formed from a relatively thin (0.2 to 0.5 mm, for example) sheet of copper, copper alloy, Alloy 42, Kovar, or a similar material such as are used in forming the leadframes traditionally used in the integrated circuit industry. Heatspreader 770 is easily handled and mounted using the same equipment used in the chip mount operation, for example. As in the embodiments described above, the heatspreader is mounted to the chip and substrate using a thermally conductive adhesive such as a metal-oxide-filled epoxy, for example.

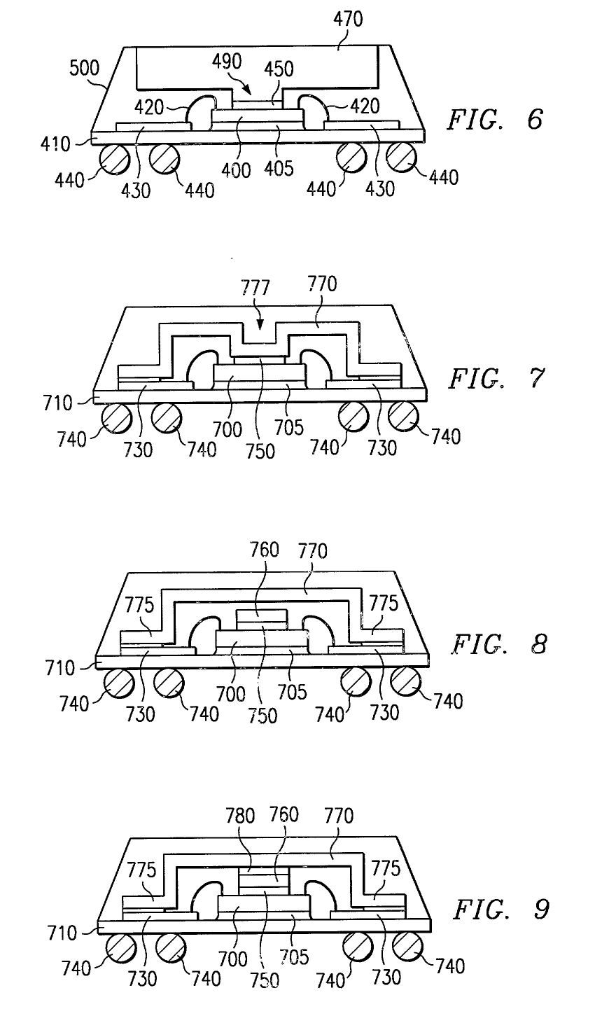

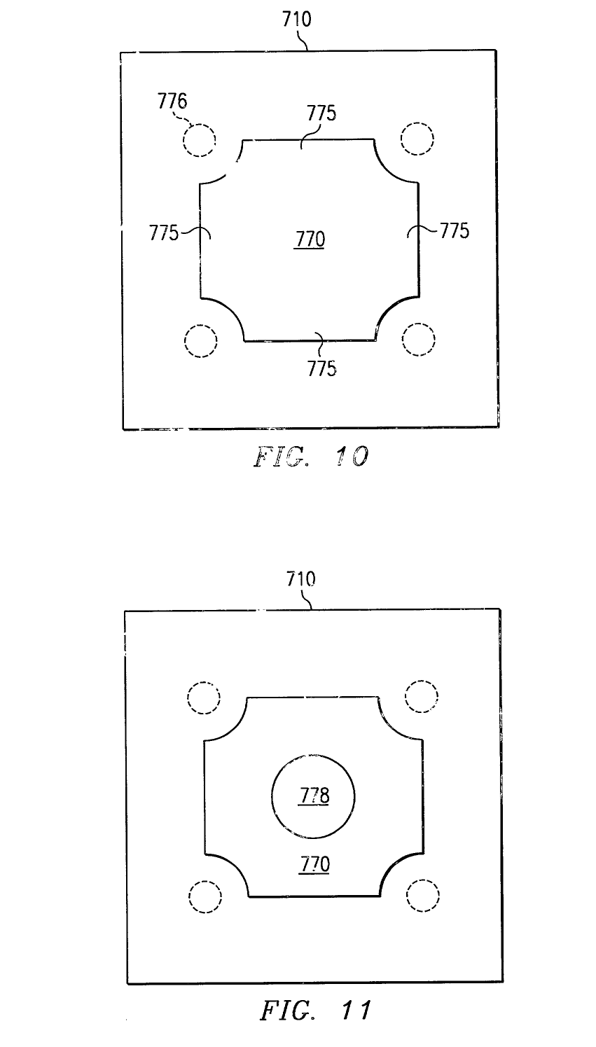

FIG. 8 shows an embodiment in which the heatspreader is attached to the substrate, but not necessarily to the chip. In this case, an approach similar to that shown in FIG. 4 is used. That is, the thermal path between the chip 700 and the heatspreader 770 is improved by mounting interposer 760 over chip 700 with thermally-conductive adhesive 750. Note that the thermal path is improved with this approach even if the interposer 760 and the heatspreader 770 are not in physical contact. However, the closer the two are, the better the thermal path. FIG. 9 is an extension of that concept and is an analogy of the embodiment shown in FIG. 5. In FIG. 9, the interposer 760 is attached to heatspreader 770 using thermally-conductive adhesive 780. It should be appreciated that, while the embodiments shown in FIGS. 7, 8 and 9 are shown with mold compound covering heatspreader 770, heatspreader 770 could also be flush with the surface of the encapsulant as well (as shown in the embodiments shown in FIGS. 4, 5, and 6).

FIG. 10 is a plan view of the embodiment shown in FIG. 8, showing the shape of the heatspreader 770 as it appears when mounted on substrate 710. Tabs 775 are used to attach the heatspreader to the substrate. The circular features 776 shown in FIG. 10 correspond to the locations of the ejector pins in the mold die that are used to force the molded package out of the die following the molding operation. It is preferable that the heatspreader be designed to avoid the ejector pin locations, hence the heatspreader shown in FIG. 10 includes rounded corners. FIG. 11 shows another heatspreader configuration. In this case the heatspreader 770 corresponds to that shown in FIG. 7, in which the heatspreader is designed to contact chip 700. The “U”-shaped portion 777 of the heatspreader shown in FIG. 7 corresponds to the round feature 777 in FIG. 11. It should be appreciated that following the molding operation, the molded surface of the package can be either planar, or can include a corresponding circular depression 778, depending upon the molding techniques used (e.g. the mold die can include a relief feature to create the depression). Additionally, it should be appreciated that the shape of the heatspreader 770 can take many forms depending upon factors relating to the tooling used to form the heatspreader (e.g. by punching) or upon factors relating to assembling the various package components.

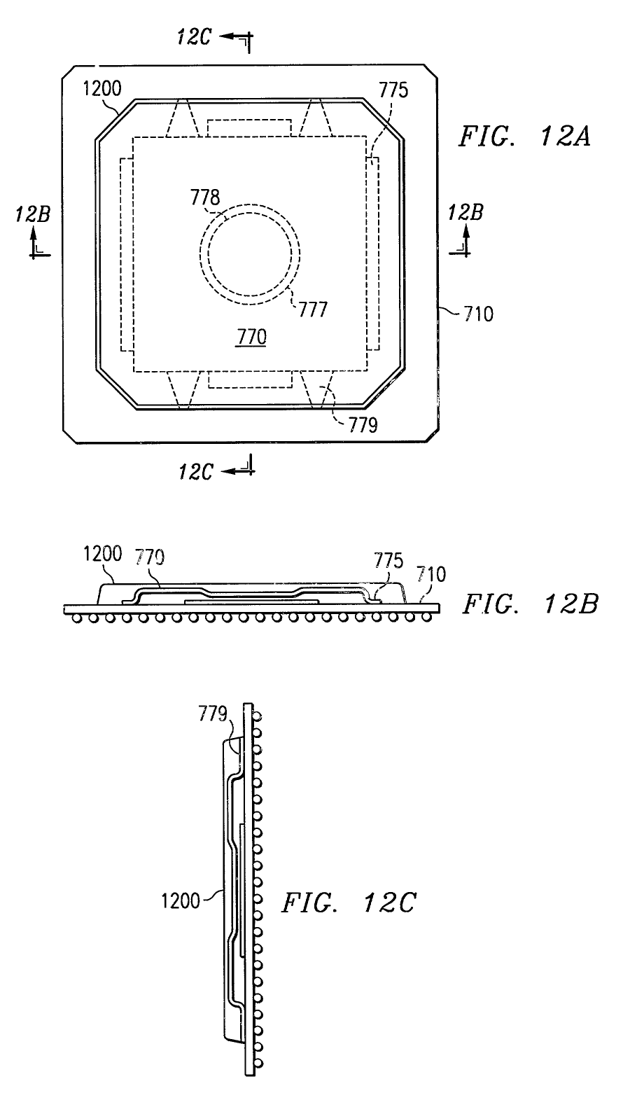

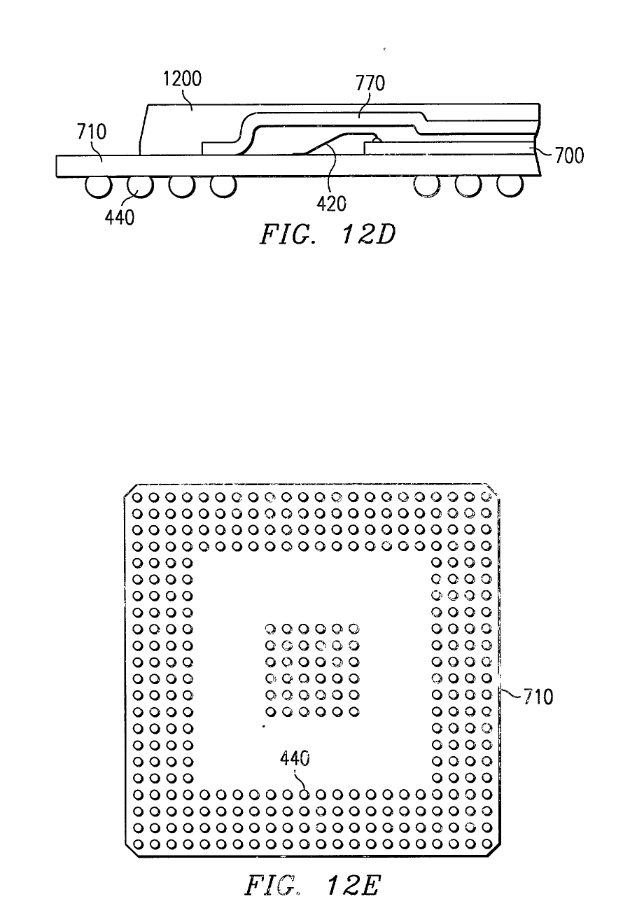

FIGS. 12a to 12e are various views of another embodiment package. FIG. 12a is a plan view of the package showing a 23 mm×23 mm substrate 710 and the outline of encapsulant 1200. Heatspreader 770 is shown in dashed lines as it is covered with encapsulant 1200. Round feature 777 is similar to the like-numbered feature shown in FIG. 7. In this embodiment the encapsulant surface has a depression 778 which is similar to the like-numbered feature shown in FIG. 11. In addition to tabs 775 used to attach heatspreader 770 to the substrate, this embodiment includes additional tabs 779 which extend to the edge of encapsulant 1200. FIG. 12b is a front-side, cross-sectional view of the package showing the shape of heatspreader 770. The right-side, cross-sectional view shown in FIG. 12c shows additional tabs 779 extending to the edge of encapsulant 1200. FIG. 12d is a detailed view of a portion of the cross-sectional diagram of FIG. 12b, making clear the relationship of the heatspreader 770 with the chip 700, bond wires 420, substrate 710, encapsulant 1200, and solder balls 440. In this embodiment, the heatspreader 770 is approximately 300 μm thick, the chip 700 is approximately 279 μm thick, the substrate is approximately 560 μm thick, and the solder balls 440 are approximately 500 μm in diameter. Encapsulant 1200 covers the uppermost portion of heatspreader 770 with a thickness of approximately 170 μm. The arc of bond wires 420 is approximately 180 μm over the surface of chip 700. Heatspreader 770 is separated from the top surface of chip 700 by approximately 223 μm at its lowest point and by approximately 420 μm at its highest point. FIG. 12e shows the underside of the package and the arrangement of solder balls 440.

While the present invention has been described according to its preferred embodiments, it is of course contemplated that modifications of, and alternatives to, these embodiments, such modifications and alternatives obtaining the advantages and benefits of this invention, will be apparent to those of ordinary skill in the art having reference to this specification and its drawings. For example, the embodiments shown herein are of the wire-bonded, tape-based, ball-grid-array type. The advantages of the invention could also be obtained from use with traditional plastic-molded leadframe packages such as the Quad Flat Pack, as well as with packages based on resin-or ceramic-laminate substrates, along with flip-chip versions of the above. It is contemplated that such modifications and alternatives are within the scope of this invention as claimed hereinbelow.

We claim:

1. A packaged integrated circuit, comprising:
a substrate having opposing top and bottom surfaces;
a chip having opposing active and bottom surfaces, said chip mounted on said top surface of said substrate such that said bottom surface of said chip is adjacent said substrate, and said active surface of said chip is away from said substrate;
a thermally-conductive interposer mounted on said active surface of said chip; and
a heatspreader over said interposer.

2. The packaged integrated circuit of claim 1, wherein said interposer is in contact with said heatspreader.

3. The packaged integrated circuit of claim 2, wherein said interposer is attached to said heatspreader.

4. The packaged integrated circuit of claim 1, wherein said active surface of said chip is in electrical contact with said substrate through bond wires.

5. The packaged integrated circuit of claim 1 further comprising encapsulant covering said top surface of said substrate, said chip, said interposer, and at least a portion of said heatspreader.

6. A packaged integrated circuit, comprising:
a substrate having opposing top and bottom surfaces;
a chip having opposing active and bottom surfaces, said chip mounted on said top surface of said substrate such that said bottom surface of said chip is adjacent said substrate, and said active surface of said chip is away from said substrate; and
a heatspreader attached to said active surface of said chip.

7. The packaged integrated circuit of claim 6, wherein said heatspreader has opposing top and bottom surfaces, said bottom surface comprising a protrusion, and further wherein said protrusion is attached to said chip.

8. The packaged integrated circuit of claim 6, wherein said active surface of said chip is in electrical contact with said substrate through bond wires.

9. The packaged integrated circuit of claim 6 further comprising encapsulant covering said top surface of said substrate, said chip, and at least a portion of said heatspreader.

10. A packaged integrated circuit, comprising:
a substrate having opposing top and bottom surfaces;
a chip having opposing active and bottom surfaces, said chip mounted on said top surface of said substrate such that said bottom surface of said chip is adjacent said substrate, and said active surface of said chip is away from said substrate; and
a heatspreader mounted on said substrate such that said heatspreader covers said chip.

11. The packaged integrated circuit of claim 10, wherein said heatspreader is attached to said active surface of said chip.

12. The packaged integrated circuit of claim 10, further comprising a thermally-conductive interposer mounted on said active surface of said chip such that said heatspreader covers both said interposer and said chip.

13. The packaged integrated circuit of claim 12, wherein said interposer is attached to said heatspreader.

14. The packaged integrated circuit of claim 10, wherein said active surface of said chip is in electrical contact with said substrate through bond wires.

15. The packaged integrated circuit of claim 1 further comprising encapsulant covering said top surface of said substrate, said chip, and at least a portion of said heatspreader.
